(19) United States
(12) Patent Application Publication
(10) Pub. No.: US 2024/0397611 A1
(43) Pub. Date: Nov. 28, 2024

(54) WIRING BOARD

(71) Applicant: Mitsubishi Electric Corporation, Tokyo (JP)

(72) Inventors: Koji MIYAGAWA, Tokyo (JP); Tetsu OWADA, Tokyo (JP)

(73) Assignee: Mitsubishi Electric Corporation, Tokyo (JP)

(21) Appl. No.: 18/790,135

(22) Filed: Jul. 31, 2024

Related U.S. Application Data
(63) Continuation of application No. PCT/JP2022/010751, filed on Mar. 11, 2022.

(51) Int. Cl. H05K 1/02

(52) U.S. Cl. CPC H05K 1/0228; H05K 1/0298; H05K 2201/09263

(57) ABSTRACT

A wiring board includes: a board; and a wire to connect a first point and a second point as one path, and propagate a signal from the first point to the second point. The wire has a first wire portion and a second wire portion that are arranged between the first point and the second point on the path through which the signal is propagated, and propagate the signal. The first wire portion propagates the signal in a first sense along a surface of the board, and the second wire portion is disposed in such a manner that, when seen in a direction perpendicular to the surface of the board, the second wire portion is adjacent to the first wire portion in a direction crossing a direction in which the signal is propagated, and propagates the signal in the first sense.

### CROSS REFERENCE TO RELATED APPLICATIONS

This application is a Continuation of PCT International Application No. PCT/JP2022/010751, filed on Mar. 11, 2022, which is hereby expressly incorporated by reference into the present application.

### TECHNICAL FIELD

The present disclosure relates to a wiring board.

### BACKGROUND ART

Typically, a plurality of signal wires such as bus wires used for Double Data Rate Synchronous Dynamic Random Access Memory (DDR-SDRAM) on a printed wiring board to perform parallel transfer are required to have equal lengths in order to synchronize the timing of arrival of signals conveyed by the plurality of signal wires at wire ends on the output side. There is a conventionally known printed wiring board on which a meander wire is formed. The meander wire has a plurality of signal wire lengths that are made equal to each other by intentionally causing some signal wires in a plurality of signal wires as mentioned above to make turns and meander (see Patent Literature 1).

### CITATION LIST

### Patent Literature

Patent Literature 1: JP 2006-173401 A

### SUMMARY OF INVENTION

### Technical Problem

FIG. 1 is a schematic diagram depicting a meander wire formed on a typical wiring board. In the meander wire as depicted in FIG. 1, signals are input from a wire end 1A, go through the wire that meanders, and are output from a wire end 2A. Since such a meander wire has a structure in which transfer directions of signals on mutually adjacent wires are opposite to each other, noise is likely to be generated due to mutual interference of the same signals between the adjacent wires, and the signal quality of the wiring board lowers in some cases.

The present disclosure has been made to solve the problem described above, and an object thereof is to provide a wiring board that can suppress the generation of noise at the time when signals are propagated, as compared to conventional techniques.

### Solution to Problem

A wiring board according to the present disclosure includes: a board; a first wire to connect a transmitter to transmit a signal and a receiver to receive the signal from the transmitter; and a second wire to connect the transmitter and the receiver, the second wire being formed to have a same path length as the first wire, the second wire including a wire to connect a first point and a second point as one path, and propagate a signal from the first point to the second point, in which the second wire has a first wire portion, a second wire portion, a third wire portion, and a fourth wire portion that are arranged between the first point and the second point on the path through which the signal is propagated, and propagate the signal, the first wire portion propagates the signal in a first sense along a surface of the board, the second wire portion is disposed in such a manner that, when seen in a direction perpendicular to the surface of the board, the second wire portion is adjacent to the first wire portion in a direction crossing a direction in which the signal is propagated, and propagates the signal in the first sense, the third wire portion and the fourth wire portion are formed on a layer which is at a position different from a position of a layer on which the first wire portion and the second wire portion are formed in a thickness direction of the board, the third wire portion connects a downstream end of the first wire portion and an upstream end of the second wire portion, and propagates the signal along the surface of the board in a second sense different from the first sense, and the fourth wire portion is connected to a downstream end of the second wire portion, and propagates the signal in the second sense.

### Advantageous Effects of Invention

The present disclosure can suppress the generation of noise at the time when signals are propagated, as compared to conventional techniques.

### BRIEF DESCRIPTION OF DRAWINGS

FIG. 1 is a schematic diagram depicting a typical meander wire.

FIG. 2 is a schematic diagram depicting a wiring board according to a first embodiment.

FIG. 3 is a schematic diagram depicting a second wire according to the first embodiment.

FIG. 4 is a schematic diagram depicting an example of senses in which signals on the second wire according to the first embodiment are propagated.

FIG. 5 is a schematic diagram depicting a second wire according to a second embodiment.

FIG. 6 is a schematic diagram depicting a second wire according to a third embodiment.

### DESCRIPTION OF EMBODIMENTS

Hereinbelow, embodiments according to the present disclosure are explained in detail with reference to the figures.

### First Embodiment

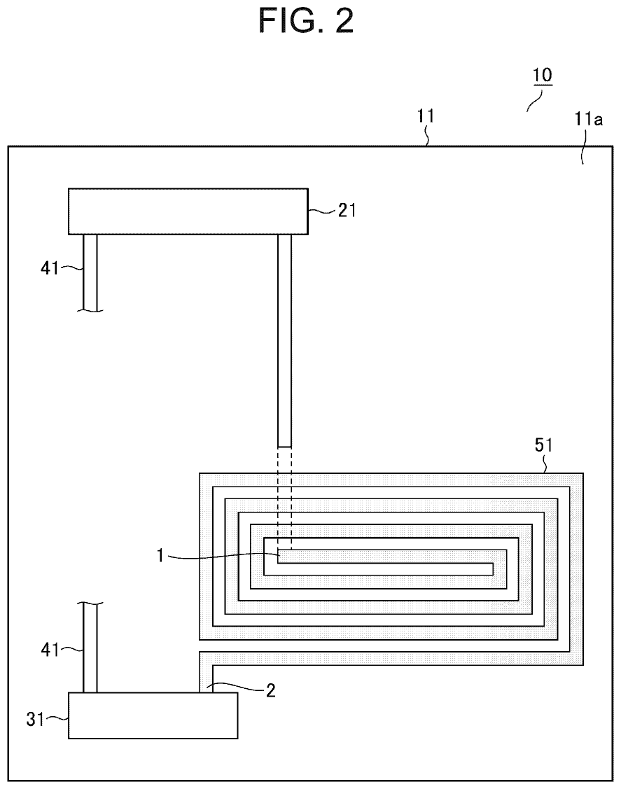

FIG. 2 is a schematic diagram depicting a wiring board 10 according to the first embodiment when seen in a direction perpendicular to a surface of the wiring board 10 (a surface 11a of a board 11 mentioned later). The wiring board 10 includes the board 11, and a first wire 41 and a second wire 51 that are formed on the board 11, and propagate signals.

For example, the wiring board 10 is a printed wiring board in which the first wire 41 and the second wire 51 which are printed wires of conductors are formed by a print technology on the board 11 which is a multilayer board having therein a plurality of inner layers (not depicted) formed along the board surface 11a. In addition, for example, the first wire 41 and the second wire 51 are bus wires including a plurality of signal wires for DDR or the like. Note that the first wire 41 and the second wire 51 are formed on an inner layer of the board 11, but both are illustrated by using solid lines for visibility in FIG. 2. In addition, the layer on which the first wire 41 and the second wire are formed is sandwiched by ground layers (not depicted) to be grounded at the time of use of the wiring board 10.

The wiring board 10 is provided with a transmitting unit 21 to transmit signals, and a receiving unit 31 to receive the signals transmitted by the transmitting unit 21. The wiring board 10, the transmitting unit 21, and the receiving unit 31 are included in a printed circuit board 10A. For example, the transmitting unit 21 and the receiving unit 31 are integrated circuits, processing apparatuses, or the like such as Integrated Circuits (IC), Central Processing Units (CPU), or Field-Programmable Gate Arrays (FPGA).

Signals transmitted by the transmitting unit 21 are propagated to the receiving unit 31 by parallel transfer via the first wire 41 and the second wire 51. Accordingly, in order to synchronize the timing of arrival of signals transmitted by the transmitting unit 21 at the receiving unit 31 through the first wire 41 and the timing of arrival of signals transmitted by the transmitting unit 21 at the receiving unit 31 through the second wire 51, the first wire 41 and the second wire 51 are required to have equal lengths on signal propagation paths from the transmitting unit 21 to the receiving unit 31. The second wire 51 according to the first embodiment is a delay wire formed to have a wire length which is equal to the wire length of the first wire 41 by having an intentionally extended wire length.

The second wire 51 does not have a branching point or a junction point between a first point 1 and a second point 2 which are connected by one path formed on a single surface. The second wire 51 is configured in such a manner that signals input from an end on the side of the transmitting unit 21 are propagated to the first point 1, the signals having passed through the first point 1 are propagated to the second point 2, and the signals having passed through the second point 2 are propagated toward the receiving unit 31, and output from an end on the side of the receiving unit 31 to the receiving unit 31.

A wire forming the path between the first point 1 and the second point 2 is formed on a single layer, and a wire forming the path between the end on the side of the transmitting unit 21 and the first point is at least partially formed on a layer which is different from the layer of the wire forming the path between the first point 1 and the second point 2. For example, signals from the layer which is different from the layer of the wire forming the path between the first point 1 and the second point 2 are input to the first point 1 via a signal via or the like.

Note that the wiring board 10 only has to be one that propagates signals transmitted by the transmitting unit 21 to the receiving unit 31 via the first wire 41 and the second wire 51, and may have configuration not of integrated circuits or processing apparatuses mentioned above. In addition, the wiring board 10 may have a component other than the transmitting unit 21 and the receiving unit 31 mounted thereon. Wires other than those that propagate signals from the transmitting unit 21 to the receiving unit 31 may also be formed on the wiring board 10. The wiring board 10 may also include wires other than the first wire 41 and the second wire 51 that propagate signals between the transmitting unit 21 and the receiving unit 31.

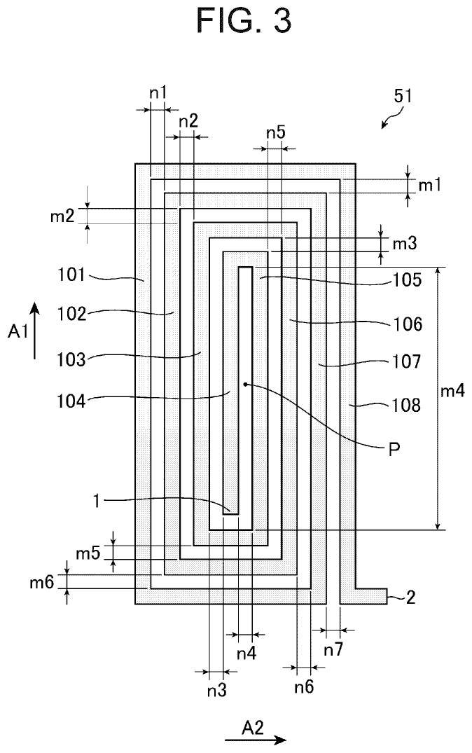

Next, details of the second wire 51 according to the first embodiment are explained with reference to FIG. 3. FIG. 3 is a schematic diagram depicting a part of the second wire 51 according to the first embodiment when seen in a direction perpendicular to the surface 11a of the board 11. Note that, in the following explanation of the second wire 51, the side of the transmitting unit 21 is also referred to as the upstream side, and the side of the receiving unit 31 is also referred to as the downstream side.

On the path between the first point 1 and the second point 2, the second wire 51 has a first wire portion 101, a second wire portion 102, a third wire portion 103, a fourth wire portion 104, a fifth wire portion 105, a sixth wire portion 106, a seventh wire portion 107, and an eighth wire portion 108 that are formed along a first direction A1 depicted in FIG. 3. Note that the first direction A1 includes a first sense and a second sense in the first embodiment.

In addition, in the second wire 51: the downstream end of the fourth wire portion 104 and the upstream end of the fifth wire portion 105 are connected by a wire formed along a crossing direction A2 crossing the first direction A1; the downstream end of the fifth wire portion 105 and the upstream end of the third wire portion 103 are connected by a wire formed along the crossing direction A2; the downstream end of the third wire portion 103 and the upstream end of the sixth wire portion 106 are connected by a wire formed along the crossing direction A2; the downstream end of the sixth wire portion 106 and the upstream end of the second wire portion 102 are connected by a wire formed along the crossing direction A2; the downstream end of the second wire portion 102 and the upstream end of the seventh wire portion 107 are connected by a wire formed along the crossing direction A2; the downstream end of the seventh wire portion 107 and the upstream end of the first wire portion 101 are connected by a wire formed along the crossing direction A2; and the downstream end of the first wire portion 101 and the upstream end of the eighth wire portion 108 are connected by a wire formed along the crossing direction A2.

In addition, the second wire 51 is formed in such a manner that the distance between a predetermined point P and the path from the first point 1 to the second point 2 gradually increases as the path goes around the predetermined point P from the upstream side toward the downstream side about the point P. In other words, the path of the second wire 51 from the first point 1 to the second point 2 is formed spirally about the predetermined point P.

In addition, the second wire portion 102 is disposed in the second wire 51 in such a manner that, when seen in the direction perpendicular to the board surface 11a, the second wire portion 102 is adjacent to and at a position closest to the first wire portion 101 and the third wire portion 103 in the crossing direction A2 among the portions formed along the first direction A1 (distance n1=distance n2).

In addition, the third wire portion 103 is disposed in the second wire 51 in such a manner that, when seen in the direction perpendicular to the board surface 11a, the third wire portion 103 is adjacent to and at a position closest to the second wire portion 102 and the fourth wire portion 104 in the crossing direction A2 among the portions formed along the first direction A1 (distance n2=distance n3).

In addition, the fourth wire portion 104 is disposed in the second wire 51 in such a manner that, when seen in the direction perpendicular to the board surface 11a, the fourth wire portion 104 is adjacent to and at a position closest to the third wire portion 103 and the fifth wire portion 105 in the crossing direction A2 among the portions formed along the first direction A1 (distance n3=distance n4).

In addition, the fifth wire portion 105 is disposed in the second wire 51 in such a manner that, when seen in the direction perpendicular to the board surface 11a, the fifth wire portion 105 is adjacent to and at a position closest to the fourth wire portion 104 and the sixth wire portion 106 in the crossing direction A2 among the portions formed along the first direction A1 (distance n4=distance n5).

In addition, the sixth wire portion 106 is disposed in the second wire 51 in such a manner that, when seen in the direction perpendicular to the board surface 11a, the sixth wire portion 106 is adjacent to and at a position closest to the fifth wire portion 105 and the seventh wire portion 107 in the crossing direction A2 among the portions formed along the first direction A1 (distance n5=distance n6).

In addition, the seventh wire portion 107 is disposed in the second wire 51 in such a manner that, when seen in the direction perpendicular to the board surface 11a, the seventh wire portion 107 is adjacent to and at a position closest to the sixth wire portion 106 and the eighth wire portion 108 in the crossing direction A2 among the portions formed along the first direction A1 (distance n6=distance n7).

In addition, the portion in the second wire 51 connecting the downstream end of the second wire portion 102 and the upstream end of the seventh wire portion 107 is disposed in such a manner that, when seen in the direction perpendicular to the board surface 11a, the portion is adjacent to and at a position closest to the portion connecting the downstream end of the first wire portion 101 and the upstream end of the eighth wire portion 108, and the portion connecting the downstream end of the third wire portion 103 and the upstream end of the sixth wire portion 106 in the first direction A1 among the portions formed along the crossing direction A2 (distance m1=distance m2).

In addition, the portion in the second wire 51 connecting the downstream end of the third wire portion 103 and the upstream end of the sixth wire portion 106 is disposed in such a manner that, when seen in the direction perpendicular to the board surface 11a, the portion is adjacent to and at a position closest to the portion connecting the downstream end of the second wire portion 102 and the upstream end of the seventh wire portion 107, and the portion connecting the downstream end of the fourth wire portion 104 and the upstream end of the fifth wire portion 105 in the first direction A1 among the portions formed along the crossing direction A2 (distance m2=distance m3).

In addition, the portion in the second wire 51 connecting the downstream end of the sixth wire portion 106 and the upstream end of the second wire portion 102 is disposed in such a manner that, when seen in the direction perpendicular to the board surface 11a, the portion is adjacent to and at a position closest to the portion connecting the downstream end of the seventh wire portion 107 and the upstream end of the first wire portion 101, and the portion connecting the downstream end of the fifth wire portion 105 and the upstream end of the third wire portion 103 in the first direction A1 among the portions formed along the crossing direction A2 (distance m5=distance m6).

In addition, when seen in the direction perpendicular to the board surface 11a, in the second wire 51, a distance m4 between the portion connecting the downstream end of the fourth wire portion 104 and the upstream end of the fifth wire portion 105 and the portion connecting the downstream end of the fifth wire portion 105 and the upstream end of the third wire portion 103 is longer than m3 and m5.

By being formed in this manner, the second wire 51 propagates signals input from the first point 1 through the fourth wire portion 104, the fifth wire portion 105, the third wire portion 103, the sixth wire portion 106, the second wire portion 102, the seventh wire portion 107, the first wire portion 101, and the eighth wire portion 108 in this order. The second wire 51 is formed in such a manner that there is a time delay of a signal input from the first point 1 until the signal reaches the second point 2, as compared with a case where the first point 1 and the second point 2 are connected linearly.

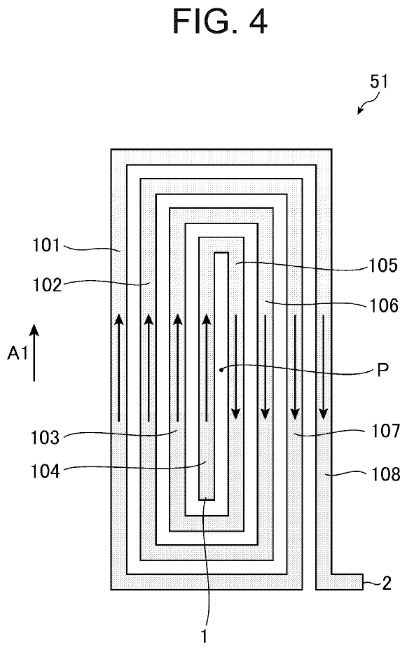

Next, senses of signals that are propagated through the second wire 51 according to the first embodiment are explained with reference to FIG. 4. FIG. 4 is a schematic diagram depicting an example of senses in which signals on the second wire 51 according to the first embodiment are propagated.

The second wire portion 102 is disposed in the second wire 51 in such a manner that the second wire portion 102 is adjacent to the first wire portion 101 in the crossing direction A2 which is a direction crossing the first direction A1 which is a direction in which signals are propagated. The second wire portion 102 propagates signals in the same sense as a sense in which the first wire portion 101 propagates signals. In addition, on the layer on which the first wire portion 101 and the second wire portion 102 are formed and between the first wire portion 101 and the second wire portion 102, the second wire 51 does not have a wire that transmits signals in a sense opposite to the sense in which the first wire portion 101 propagates signals.

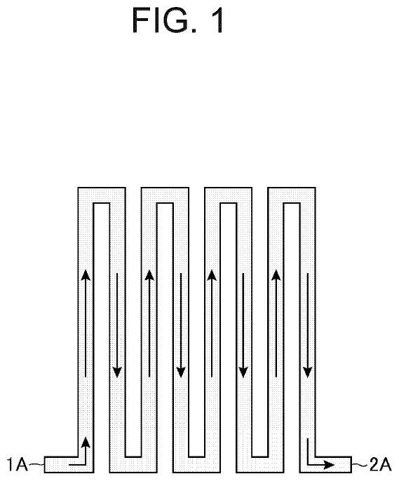

For example, in a case where signals are propagated in mutually opposite senses through proximate wires as in a typical meander wire (see FIG. 1) formed to meander multiple times, noise due to crosstalk is superimposed repeatedly on the signals themselves again and again; as a result, a phenomenon called delay reduction in which a wave-shape edge appears to have preceded occurs.

Since the first wire portion 101 and the second wire portion 102 in the second wire 51 according to the first embodiment propagate signals in the same sense, the influence of noise due to mutual interference of the same signals caused by self-coupling between the first wire portion 101 and the second wire portion 102 can be suppressed. Since the signal quality can be improved as compared to conventional techniques thereby, for example, it is possible to make it easier to perform signal-timing designing for bus wires or the like through which signals are propagated fast. In addition, since the necessity for increasing the distance between signal wires that are arranged proximately for the purpose of preventing signal interference lowers, it becomes possible to reduce the size of the wiring board.

Note that whereas the first wire 41 and the second wire 51 according to the first embodiment are formed on the same inner layer of the board 11, and the inner layer on which the first wire 41 and the second wire 51 are formed is sandwiched by the ground layers to be grounded at the time of use of the wiring board 10, this is not the sole example. The first wire and the second wire may partially be formed on a surface layer exposed to the front surface or the back surface of the board 11 or may entirely be formed on the surface layer, but a higher noise suppression effect can be attained when signals are propagated if the second wire 51 is entirely formed on the inner layer. In addition, although a higher noise suppression effect can be attained if the second wire 51 is entirely sandwiched by ground patterns formed on the ground layers, the second wire 51 may be disposed without being sandwiched by the ground patterns partially or entirely.

In addition, in a case where the board has a first inner layer and a second inner layer that are at mutually different positions in the thickness direction, that is, the direction perpendicular to the board surface 11a, the second wire may partially be formed on the first inner layer, and partially be formed on the second inner layer, or may be formed over three or more inner layers. In addition, the first wire portion and the second wire portion may be formed on different inner layers. For example, the first wire portion may be formed on the first inner layer, and the second wire portion may be formed on the second inner layer. By forming adjacent wires on mutually different inner layers in this manner, the generation of noise at the time when signals are propagated can be suppressed further.

In addition, whereas the second wire 51 according to the first embodiment is configured in such a manner that the second wire 51 propagates signals from the first point 1 close to the point P, which is the center of the spirally formed wire, toward the second point 2 far from the point P, this is not the sole example. The second wire may be one that propagates signals from the second point toward the center of the spiral to the first point, or may be one in which senses of the propagation of signals switch alternately between a sense from the transmitting unit 21 to the receiving unit 31 and a sense from the receiving unit 31 to the transmitting unit 21.

In addition, the second wire 51 according to the first embodiment has a plurality of sections formed therein in each of which portions are arranged to be mutually adjacent in the direction crossing the direction in which signals are propagated when seen in the direction perpendicular to the board surface 11a, and propagate the signals in the same sense, such as the first wire portion 101 and the second wire portion 102, and the third wire portion 103 and the fourth wire portion 104. However, this is not the sole example. The second wire may have just one section in which portions are arranged to be mutually adjacent in the direction crossing the direction in which signals are propagated when seen in the direction perpendicular to the board surface 11a, and propagate the signals in the same sense. Alternatively, the second wire may be formed in such a manner that the second wire has a plurality of combinations of sections in each of which portions propagate signals in the same sense, and senses in which signals are propagated in each of the combinations are different from each other. For example, in a case where the first wire portion and the second wire portion propagate signals in the mutually same sense, and the third wire portion and the fourth wire portion propagate signals in the mutually same sense, the sense (first sense) in which signals on the first wire portion are propagated and the sense (second sense) in which signals on the third wire portion are propagated may be different from each other. The sense in which signals on the first wire portion are propagated and the sense in which signals on the third wire portion are propagated may be opposite to each other. Alternatively, the sense in which signals on the first wire portion are propagated and the sense in which signals on the third wire portion are propagated may cross each other.

In addition, as mentioned above, senses in which signals are propagated in the fourth wire portion 104 and the fifth wire portion 105 are opposite to each other. The second wire 51 according to the first embodiment is formed in such a manner that there is just one section in which portions are arranged closest to each other in the direction crossing the direction in which signals are propagated when seen in the direction perpendicular to the board surface 11a, and propagate the signals in mutually opposite senses, such as the fourth wire portion 104 and the fifth wire portion 105. However, this is not the sole example. The second wire may be formed in such a manner that there is no section in which portions are arranged closest to each other in the direction crossing the direction in which signals are propagated when seen in the direction perpendicular to the board surface 11a, and propagate the signals in mutually opposite senses. For example, in a case where the second wire is formed in such a manner that the distance n4 is longer than the distance n3, the second wire is formed in such a manner that there is no section in which portions are formed along the mutually same direction, also are arranged adjacent to and closest to each other, and propagate signals in mutually opposite senses.

In addition, the second wire may be formed in such a manner that there are a plurality of sections in each of which portions are arranged closest to each other in the direction crossing the direction in which signals are propagated when seen in the direction perpendicular to the board surface 11a, and propagate the signals in mutually opposite senses.

### Second Embodiment

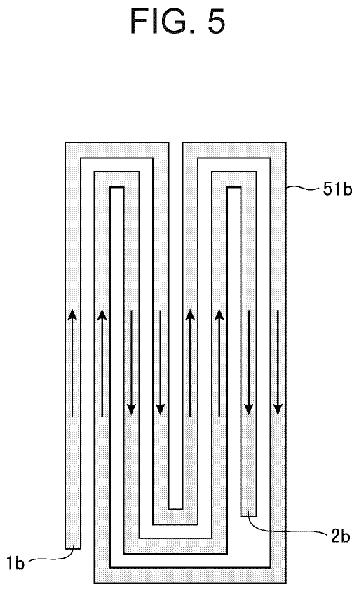

Next, a second wire 51b according to the second embodiment is explained with reference to FIG. 5. FIG. 5 is a schematic diagram depicting a part of the second wire 51b according to the second embodiment when seen in a direction perpendicular to a surface 11a of a board 11. The second wire 51b according to the second embodiment has a signal conveyance path which is different from that in the second wire 51 according to the first embodiment, but, in other respects, has configuration and features that are similar to those of the second wire 51 according to the first embodiment. Explanation of content similar to that in the first embodiment is omitted.

The second wire 51b according to the second embodiment is formed in such a manner that there are a plurality of sections in each of which portions are arranged closest to each other in the direction crossing the direction in which signals are propagated when seen in the direction perpendicular to the board surface 11a, and propagate the signals in mutually opposite senses. The second wire 51b propagates signals input from a first point 1b, and outputs the signals from a second point 2b.

Note that whereas each of the second wire 51 according to the first embodiment and the second wire 51b according to the second embodiment has a path between the first point and the second point that is formed on a single surface (single layer), this is not the sole example. The path between the first point and the second point, in other words, a portion where the wire is intentionally extended in order to make the wire length thereof equal to the wire length of another wire, of the second wire may be formed over a plurality of layers.

### Third Embodiment

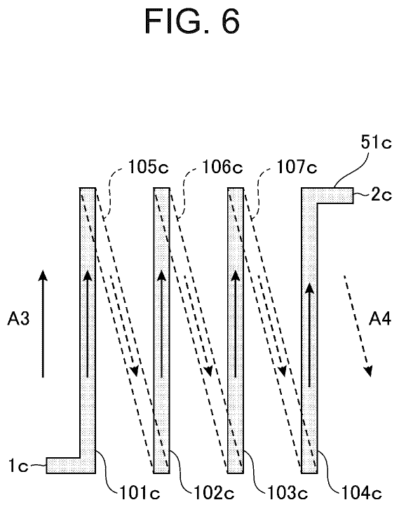

Next, a second wire 51c according to the third embodiment is explained with reference to FIG. 6. FIG. 6 is a schematic diagram depicting a part of the second wire 51c according to the third embodiment when seen in a direction perpendicular to a surface 11a of a board 11. The second wire 51c according to the third embodiment has a signal conveyance path which is different from that in the second wire 51 according to the first embodiment, but, in other respects, has configuration and features that are similar to those of the second wire 51 according to the first embodiment. Explanation of content similar to that in the first embodiment is omitted.

The second wire 51c according to the third embodiment has a path between a first point 1c and a second point 2c that is formed over a plurality of layers of the board 11 which is a multilayer board. Specifically, on the path between the first point 1c and the second point 2c, the second wire 51c has a first wire portion 101c, a second wire portion 102c, a third wire portion 103c, a fourth wire portion 104c, a fifth wire portion 105c, a sixth wire portion 106c, and a seventh wire portion 107c.

In addition, in the second wire 51c, the downstream end of the first wire portion 101c and the upstream end of the fifth wire portion 105c are connected, the downstream end of the fifth wire portion 105c and the upstream end of the second wire portion 102c are connected, the downstream end of the second wire portion 102c and the upstream end of the sixth wire portion 106c are connected, the downstream end of the sixth wire portion 106c and the upstream end of the third wire portion 103c are connected, the downstream end of the third wire portion 103c and the upstream end of the seventh wire portion 107c are connected, and the downstream end of the seventh wire portion 107c and the upstream end of the fourth wire portion 104c are connected. By being configured in this manner, the second wire 51c conveys signals input from the first point 1c along the first wire portion 101c, the fifth wire portion 105c, the second wire portion 102c, the sixth wire portion 106c, the third wire portion 103c, the seventh wire portion 107c, and the fourth wire portion 104c in this order as represented by arrows depicted in FIG. 6, and outputs the signals from the second point 2c.

The first wire portion 101c, the second wire portion 102c, the third wire portion 103c, and the fourth wire portion 104c are formed on a first layer (not depicted) which is a single layer, and the fifth wire portion 105c, the sixth wire portion 106c, and the seventh wire portion 107c are formed on a second layer which is at a position different from the position of the first layer in the direction crossing the board surface. In addition, the first wire portion 101c, the second wire portion 102c, the third wire portion 103c, and the fourth wire portion 104c propagate signals in the mutually same sense, a third direction A3 (first sense), and the fifth wire portion 105c, the sixth wire portion 106c, and the seventh wire portion 107c propagate signals in the mutually same sense which is different from the sense of the first wire portion 101c. For example, the fifth wire portion 105c, the sixth wire portion 106c, and the seventh wire portion 107c propagate signals along the mutually same sense, a fourth direction A4 which is a direction crossing the direction in which the first wire portion 101c propagates signals.

In the wires formed on the first layer in the wires of the second wire 51c, when seen in the direction perpendicular to the board surface, the second wire portion 102c is disposed to be adjacent to and at a position closest to the first wire portion 101c and the third wire portion 103c in a direction crossing the third direction A3 among the portions formed along the third direction A3. In other words, on the first layer, the second wire 51c does not have, between the first wire portion 101c and the second wire portion 102c, and between the second wire portion 102c and the third wire portion 103c, a wire that transmits signals in a sense opposite to the sense in which the first wire portion 101c propagates signals.

In addition, in the wires formed on the first layer in the wires of the second wire 51c, when seen in the direction perpendicular to the board surface, the fourth wire portion 104c is disposed to be adjacent to and at a position closest to the third wire portion 103c in a direction crossing the third direction A3 among the portions formed along the third direction A3. In other words, on the first layer, the second wire 51c does not have, between the third wire portion 103c and the fourth wire portion 104c, a wire that transmits signals in a sense opposite to the sense in which the third wire portion 103c propagates signals.

By being configured in this manner, the second wire 51c according to the third embodiment propagates signals in the same sense through the first wire portion 101c, the second wire portion 102c, the third wire portion 103c, and the fourth wire portion 104c that are arranged mutually adjacent on a single layer, and accordingly can suppress the influence of noise due to mutual interference of the same signals caused by self-coupling between the first wire portion 101c and the second wire portion 102c, between the second wire portion 102c and the third wire portion 103c, and between the third wire portion 103c and the fourth wire portion 104c.

In addition, the path between the first point 1c and the second point 2c of the second wire 51c according to the third embodiment does not have, over a plurality of layers of the board, a section in which portions propagate signals in mutually opposite senses when seen in the direction perpendicular to the board surface. Thus, the second wire 51c can suppress the influence of noise due to mutual interference of the same signals caused by self-coupling.

Note that the shapes of wires are not limited to linearly formed shapes in any of the embodiments mentioned above. Wires may be formed curvilinearly, may be formed with combinations of straight lines and curves, or may be formed in a curvilinear spiral shape. In a case where the second wire is formed in a curvilinear spiral shape, a section in which portions propagate signals in mutually opposite senses and which is at the central portion becomes smaller, and accordingly it is possible to attain a high noise-generation suppression effect at the time of the propagation of signals.

Note that, in the present disclosure, any combinations of embodiments, modifications of any components in embodiments, or omission of any components in embodiments are/is possible.

### INDUSTRIAL APPLICABILITY

The wiring board according to the present disclosure can be used for improving the signal quality when signals are propagated.

### REFERENCE SIGNS LIST

1, 1b, 1c: first point, 2, 2b, 2c: second point, 10: wiring board, 11: board, 11a: board surface, 51, 51b, 51c: second wire (wire), 101, 101c: first wire portion, 102, 102c: second wire portion, 103, 103c: third wire portion, 104: fourth wire portion, A1: first direction (first sense, second sense), A2: crossing direction, A3: third direction (first sense), P: point

1. A wiring board comprising:
a board;
a first wire to connect a transmitter to transmit a signal and a receiver to receive the signal from the transmitter; and
a second wire to connect the transmitter and the receiver, the second wire being formed to have a same path length as the first wire, the second wire including a wire to connect a first point and a second point as one path, and propagate a signal from the first point to the second point, wherein
the second wire has a first wire portion, a second wire portion, a third wire portion, and a fourth wire portion that are arranged between the first point and the second point on the path through which the signal is propagated, and propagate the signal,
the first wire portion propagates the signal in a first sense along a surface of the board,
the second wire portion is disposed in such a manner that, when seen in a direction perpendicular to the surface of the board, the second wire portion is adjacent to the first wire portion in a direction crossing a direction in which the signal is propagated, and propagates the signal in the first sense,
the third wire portion and the fourth wire portion are formed on a layer which is at a position different from a position of a layer on which the first wire portion and the second wire portion are formed in a thickness direction of the board,
the third wire portion connects a downstream end of the first wire portion and an upstream end of the second wire portion, and propagates the signal along the surface of the board in a second sense different from the first sense, and
the fourth wire portion is connected to a downstream end of the second wire portion, and propagates the signal in the second sense.

2. The wiring board according to claim 1, wherein
the board is a multilayer board having an inner layer, and
the first wire portion and the second wire portion are formed on the inner layer.

3. The wiring board according to claim 1, wherein the second wire is formed in such a manner that the number of sections in each of which portions are disposed closest to each other in the direction crossing the direction in which the signal is propagated when seen in the direction perpendicular to the surface of the board, and propagate the signal in mutually opposite senses is equal to or smaller than one.

4. The wiring board according to claim 1, wherein the first wire portion and the second wire portion are formed on a single surface.

5. The wiring board according to claim 2, wherein
the inner layer is a first inner layer,
the board has a second inner layer which is at a position different from a position of the first inner layer in the thickness direction of the board,
the first wire portion is formed on the first inner layer, and
the second wire portion is formed on the second inner layer.
